(19) United States
(12) Patent Application Publication
(10) Pub. No.: US 2013/0033158 A1
(43) Pub. Date: Feb. 7, 2013

(54) CASING SHELL, ESPECIALLY FOR PORTABLE ELECTRICAL DEVICES, AND METHOD FOR THEIR PRODUCTION

(71) Applicants: Winfried SCHMIDT, Wassertruedingen (DE); Marco WACKER, Wilhermsdorf (DE)

(72) Inventors: Winfried SCHMIDT, Wassertruedingen (DE); Marco WACKER, Wilhermsdorf (DE)

(73) Assignee: OECHSLER, Ansbach (DE)

(21) Appl. No.: 13/564,235

(22) Filed: Aug. 1, 2012

(30) Foreign Application Priority Data
Aug. 2, 2011 (DE) 20 2011 103 932

(51) Int. Cl. H05K 5/03; B29C 45/14

(52) U.S. Cl. 312/223.1; 264/257

(57) ABSTRACT

A casing shell for electrical measuring, control or communication devices, in particular the casing module of a cell phone, has a high bending and torsional stiffness despite extremely low wall strength with a completely flat outside surface, since the flat blank of a fiber-reinforced matting in an injection mold is back-injected along the matting edge area in striplike form with a preferably also fiber-reinforced frame, including molded functional elements and preferably comprising the cut edges of the matting in an L-shape.

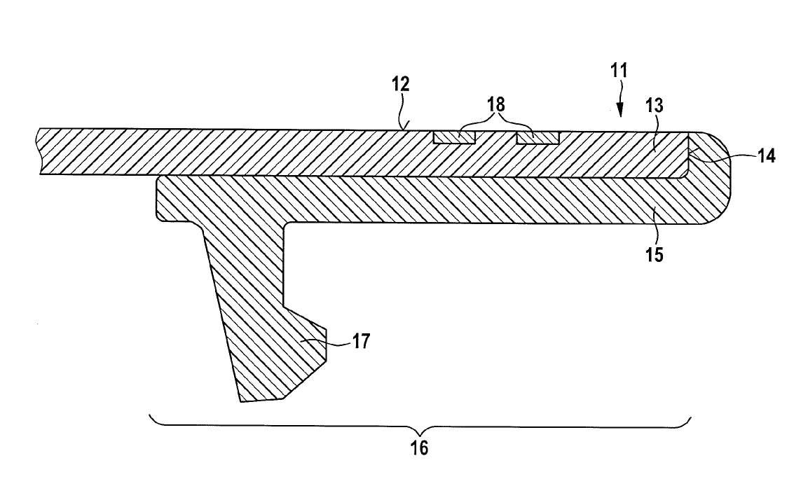

The invention relates to a casing shell and a method for their production.

Such a casing shell is known from EP 1 219 401 A2 as a rear casing cover for small electronic devices such as, in particular, cell phones. For the production of such a casing shell, a flat blank of matting that consists of carbon fibers that are oriented orthogonally to one another, in a sandwich between thermoplastic material or impregnated with thermoplastic material, is converted in a deep-draw form to form a warp-resistant and thus tank-like intermediate product, by which process, at the same time, thermoplastic material is pressed into the structure of the fiber matting. The edges of that intermediate product are cut, before it is placed in an injection mold, and on both sides it is completely provided with a sprayed-on outer cover layer as well as an inner cover layer. In this case, massive functional elements are molded on the inner cover layer, which project from the tank bottom into the interior of the tank.

By the application of the two-sided, smooth outer and profiled inner cover layers on the tank-like deep-drawn matting, such a casing shell obtains, however, a thickness that is a multiple of the central fiber matting.

Sealing elements between two such casing shells that work together in a casing call for additional required space for receiving profiles for the properly aligned and suitable positioning of such seals. In practice, it is very problematic to apply, for example, foils for improving the surface feel or the appearance on such curved outside surfaces and to secure them tightly to the shell especially in the surrounding area of the shell edge that is bent with a small transfer radius. And when this is a convex rear cover of a casing housing, the device can then be laid down on a flat solid support but not operated in a stable manner since, for example, when a key was pressed on the front side of the device, the convex rear side would rock away.

In recognition of the conditions depicted, the technical problem of this invention is based, with an additional option of simplifying the production process, on providing extraordinarily flat and thin, i.e., also light but nevertheless dimensionally stable casing shells with excellent properties with respect to surface feel and optics as well.

This object is achieved according to the invention according to the significant features that are indicated in the main claims. The solution is based on an unexpected departure from the intermediate step of the deep-draw deformation of a fiber-reinforced plastic matting that was previously considered indispensable for forming the tank-like intermediate product. Instead, a plastic-impregnated or plastic-laminated flat, contour-cut tissue or fabric matting is now directly introduced into an injection mold and therein sprayed out onto its later casing inside with a frame that is made of reinforced plastic; hence, at the same time, a molding of, for example, functional elements that have a non-positive or positive action on this inner side can also be part of the process.

By virtue of such a plastic frame that is sprayed onto the completely flat plastic-impregnated matting—while completely eliminating a separate deep-draw process step—, said frame does not, depending on the structural conditions under which such a casing shell is used, have to run uninterruptedly along the entire edge of the matting; in any case, the already mechanically highly resilient fiber matting gains additional bending and warp resistance—without thereby having to resort to the technologically expensive deep-draw process that is critical with respect to local material stress for creating a convex tank.

Reasonably-priced matting available as precursor material is rarely completely flat, and its strength usually has noticeable tolerance constraints. According to a further development of the invention, before it is introduced into the injection mold for back-spraying with the frame, the matting is therefore flattened to a certain extent over its entire surface. Such defined smooth pressing of the matting with the supply of heat up to the specified matting thickness can be done in a technologically non-critical independent process step upstream from the injection step, but it can also be provided to move this process step into the injection mold, in which the matting is then first pressed symmetrically by means of a large-surface die and then is immediately back-injected in this mold. In any case, it is ensured that the outside surface of the casing shell that is back-injected with the frame is completely smooth and flat over its entire extension up to its edge.

Preferably, the injection mold for receiving the plastic-impregnated flat matting is also designed in such a way that the plastic frame that is applied on the later casing shell's inside surface in a strip-like manner along the edge of the matting extends over the front of the matting, i.e., its blank edge, in the shape of an L. Then, the front of the short L-leg ends flush in the plane of the outside surface of the matting. Such an angled frame structure that is L-shaped in cross-section yields a further elevated stiffness of the matting-frame composite and in addition ensures a geometrically exact shaping corresponding to the structural requirement of the interaction of this casing shell in the dividing gap with the other casing, which can be hermetically sealed by means of the completely flat rear or lower casing shell in the form of a cover.

Typically, the subject of the invention is an intact casing subshell. Also, however, through holes, for example for inserting plug elements, displays or key switches, are possible. Such through holes can be made even in the flat blank of the impregnated tissue matting or core fiber matting, but they can also be punched out during the flattening of the matting, optionally also only in the injection mold as part of the back-injection with the frame. Stricter precision and decorative requirements can be met when such through holes are added only after the output from the injection mold, i.e., in the casing shell that is then already equipped with its frame.

According to an advantageous further development of the invention, the later outside surface of the casing shell can be equipped with decorative or marking inserts that are preferably to be embossed. To this end, it is advisable to design the contours of such inserts as metal dies on a foil, from which they can be easily detached and transferred to the outside surface of the matting, when the foil is pressed against this surface of the matting. Thus, pre-equipped with these inserts, the matting is introduced into the plate device, in which said inserts are pressed into their outside surface as part of the application of pressure and heat on the matting. When, however, the planning of the matting, as mentioned without any process step, is carried out in the injection mold immediately before the application of the frame, it then can be provided, as part of the flattening, at the same time to press the inserts in the matting surface that is then to be back-injected.

Subsequent painting, by the surface feel, optics and in particular when using a commercially available thus-mentioned easy-to-clean finish, also the scratch resistance of the outside surface of the casing shell to undergo an additional enhancement, then leads at the same time to an improvement of the adhesion of those lacquer-coated inserts that are introduced in advance in the outside surface of the casing shell.

When, in the edge area of the matting, the thickness of such inserts embossed on the outside surface relative to the thickness of the matting is selected in such a way that the matting of the printed inserts undergoes geometrically corresponding embossing on the inner side thereof or even through-punching, then a continuous connection can be imparted by such surface profiling or even a positive connection can be achieved between the matting and the frame sprayed thereon.

The outside surface of the casing shell, removed from the injection mold and completely flat in macro-evaluation, can have a rough microstructure because of the fiber-reinforced matting. As regards their leveling in the interest of a through-going smooth outside surface that is not susceptible to fouling, as it may be desired in particular also for surface-feel or optical reasons, an additional function-optimizing surface finishing is suitable. Independently of the improved binding of some inserts, it is advantageous in this sense to optimize the outside surface of the casing shell, for example, by means of foil coating or metallizing in terms of surface feel, design and function. Shell problems on the edge of the casing shell now no longer occur since the rear side of the casing shell is completely flat up to and including the frame leg that encompasses the matting cut edges.

A surface quality that is desirable for visible surfaces or handling surfaces in terms of a flat, gleaming and in particular also a self-healing, scratch-resistant surface is achieved according to this further development of the invention by a paint application that, depending on requirements, is regionally limited or else full-surface and preferably multi-layer, for example, of the above-mentioned kind. Its base coat that is to be applied relatively thickly acts as an adhesion promoter with the base, i.e., on the outside surface of the casing shell, and is used at the same time in the planning of this surface, so that its tissue-based seam structure after the base coat is hardly visible. On top of the base coat, pigments in their binders are applied in at least one additional coat, and on which as transparent and as scratch-resistant a finishing coat as possible is ultimately applied, which produces the desired gloss, provides for the light resistance of the coloring, and at the same time ensures the surface qualities.

The viscosity of the paint solvent can be set in this case according to the surface conditions and with respect to size and topography of the surface area that is to be tempered to achieve, via the flow properties, a quick, uniform wetting and thus homogeneous optical properties over the entire specified surface area, so that this thus treated matting can then be used even also as an optical component.

In particular for mechanically more highly stressed and thus harder surface areas, according to an additional further development of this invention, the use of preferably solvent-free, multi-component, in particular two-component paint for producing the gloss layer is preferred, since such a paint—because of the chemical reaction of its components—hardens without drying requirements on the surface laminated directly with it or else on a base coat.

Thus, parts of casings for electrical measuring, control and communication devices, in particular casing module shells for cell phones, are provided, which, while ensuring excellent surface feel and optics of their scratch-resistant surface despite extremely small wall thickness up to the edge of an absolutely flat design, have high bending and torsion rigidity, by flat blanks of thermoplastically impregnated long-fiber, multilayer tissue or fabric matting with a thermoplastic frame being back-injected, being molded onto the fine-membered functional elements at the same time, optionally with the introduction of inserts into the outside surface of the casing shell and with subsequent painting.

For a more detailed illustration of the invention, a flat casing shell of the type according to the invention that can be inserted in particular as a hand device-casing back, greatly enlarged somewhat to scale in the drawing, is sketched in a cutaway cross-section through its rear-framed edge area.

The casing shell 11 that is very thin in comparison to its cross-sectional dimensions has a completely flat surface on the outside. This is the outside surface 12 of a thermoplastically impregnated, flat-cut fiber matting 13. Its cut edges or front edges 14 are molded on a frame 15 that is made of thermoplastic plastic and that is L-shaped in cross-section, with which the flat matting 13 in this respect was placed in an injection mold (not shown) and was back-injected along its striplike edge area 16. In this case, functional elements 17 were molded on the frame 15 at the same time, pointing away from the matting 13, somewhat arch-shaped or rib-shaped in friction or (as sketched) acting positively like a hook. Facing away from the matting 13, the frame 15 can also be formed with groove or spring profiles (not sketched) for direct sealing action or for accommodating sealing elements.

Into the outside surface 12 of the matting 13, thin, in particular metal, inserts 18, for example as decoration or marking, were embedded as described above, whose thickness is typically less than 20% of the matting thickness. These non-positive, material or positive inserts 18 that are anchored in the outside surface 12 undergo additional securing when the outside surface 12 is finally painted, for example, for reasons of surface feel, optics or for scratch resistance or is otherwise coated, as was discussed above.

The matting 13 preferably consists of a multi-layer tissue of long intersecting fibers, which can be interwoven or interworked and can be oriented in their directions to the mechanical stress of the casing shell 11 that is to be expected. Also, however, matting 13 with tile-like, loose, undirected reinforcement fibers can be used within the scope of this invention for the flat, outwardly absolutely even casing shell 11. In this case, the reinforcement insert can be carbon fibers, but also balsam fibers or in particular PE- or PP-plastic fibers. For an often desirable high-frequency permeability of the casing shell 11 that surrounds, for example, an antenna, glass fibers or fibers that consist of aromatic polyamides (aramide) that are made especially tear-resistant are favored.

The tissue of the matting 13 is preferably laminated on both sides with a think cover layer in each case of a more reasonably-priced available thermoplastic plastic, for example elastomers based on urethane or polyamides, but also amorphous terpolymer or the impact-resistant polycarbonate can advantageously be used. The thickness of the matting 13, and thus within the frame 15, the thickness of the casing shell 11 that is completely flat on the outside up to its edge, can be as little as one millimeter and even significantly less. The thickness of the frame 15 that extends at least in places along the edge area 16 of the matting 13 is in the same order of magnitude.

For this striplike frame 15, a thermoplast is also selected, suitably a polyamide such as polycaprolactam. A good half-volume addition of glass (preferably applied to the same parts as short fibers and as spheres) yields the desirable stiffening of the matting 13 formed by the frame 15 and the necessary strength for the assembly-functional elements 17 with desirable elasticity.

A casing shell 11 for electrical measuring, control or communication devices, in particular the casing module of a cell phone, has a high bending and torsional stiffness despite extremely low wall strength up to the edge of the completely flat outside surface 12, since the flat blank of a fiber-reinforced matting 13 with a thermoplastic matrix in an injection mold is back-injected along the matting edge area 16 in striplike form with a preferably also fiber-reinforced frame 15, including molded functional elements 17, preferably comprising the cut edges 14 of the matting 13 in an L-shape.

1. Casing shell, formed from a flat blank of a matting with a thermoplastic matrix, with injection-molded, sprayed-on, functional elements that consist of also thermoplastic material, for especially portable electrical devices, characterized in that a flat matting with a frame that runs in a striplike form at least in places behind the matting edge area, including functional elements molded therein, is back-injected.

2. Casing shell according to claim 1, wherein the frame encompasses front edges of the matting in an L shape.

3. Casing shell according to claim 1, wherein the front of the frame that encompasses the matting seals off flush with the flat matting outside surface.

4. Casing shell according to claim 1, wherein the injection material for the frame has a different elasticity—and optionally tinting—than the material of the matting.

5. Casing shell according to claim 1, wherein the frame is sprayed on glass-fiber-reinforced polyamide.

6. Casing shell according to claim 1, wherein the matting is impregnated with thermoplastic plastics, such as elastomers based on urethane, polyamides, amorphous terpolymer or impact-resistant polycarbonate as a matrix.

7. Casing shell according to claim 1, wherein inserts are recessed in the flat outside surface of the matting.

8. Casing shell according to claim 1, wherein its outside surface is made optimized for design and function as well as optionally scratch-resistant by means of painting, film coating or metallization.

9. Method for the production of a casing shell according to claim 1, wherein a cut-to-length flat fiber-matting with a thermoplastic matrix is placed in an injection mold and is back-injected therein with a thermoplastic frame, including molded functional elements.

10. Method according to claim 9, wherein the matting is flattened in an adjustment step that is upstream from the injection and is applied to the thickness dimension.

11. Method according to claim 10, wherein the later outside surface of the matting and thus the casing shell are leveled in the injection mold.

12. Method according to claim 9, wherein inserts applied on the matting are immersed in the later outside surface.

13. Method according to claim 12, wherein the edge area of the matting that faces opposite the frame is punched out or even perforated by means of the inserts that are graven on the outside.
